(19) United States
(12) Patent Application Publication
(10) Pub. No.: US 2025/0118819 A1
(43) Pub. Date: Apr. 10, 2025

(54) SERIAL CONNECTION STRUCTURE OF POUCH-TYPE BATTERY CELL APPLIED TO SERIAL BATTERY CHARGING AND DISCHARGING DEVICE

(71) Applicant: GREEN POWER CO., LTD., Hwaseong-si (KR)

(72) Inventors: Jung Goo CHO, Suwon-si (KR); Kyu Min CHO, Hwaseong-si (KR)

(73) Assignee: GREEN POWER CO., LTD., Hwaseong-si (KR)

(21) Appl. No.: 18/984,495

(22) Filed: Dec. 17, 2024

Related U.S. Application Data
(63) Continuation of application No. PCT/KR2023/008359, filed on Jun. 16, 2023.

(30) Foreign Application Priority Data
Jun. 29, 2022 (KR) 10-2022-0079337

(51) Int. Cl. H01M 10/46; H01M 50/211; H01M 50/51

(52) U.S. Cl. CPC H01M 10/46; H01M 50/211; H01M 50/51

(57) ABSTRACT

The present disclosure relates to a serial connection structure of a battery cell, and more particularly, to a serial connection structure of a battery cell applied to a device that serially connects a plurality of pouch-type battery cells to perform charging and discharging, thereby dramatically shortening a cable length by simplifying a cable structure for serially connecting each battery cell and minimizing loss and cost caused by the cable.

### CROSS-REFERENCE TO RELATED APPLICATIONS

The present application is a Continuation of International Patent Application No. PCT/KR2023/008359, filed on Jun. 16, 2023, which is based upon and claims the benefit of priority to Korean Patent Application No. 10-2022-0079337, filed on Jun. 29, 2022. The disclosures of the above-listed applications are hereby incorporated by reference herein in their entirety.

### TECHNICAL FIELD

The present disclosure relates to a serial connection structure of a battery cell, and more particularly, to a serial connection structure of a pouch-type battery cell applied to a device that serially connects a plurality of pouch-type battery cells to perform charging and discharging, thereby dramatically shortening a cable length by simplifying cable structure for serially connecting each battery cell and minimizing loss and cost caused by the cable.

### BACKGROUND ART

Secondary batteries are used in various devices such as portable electronic devices, electric vehicles, and energy storage devices, and the demand for the secondary batteries is rapidly increasing due to the explosive growth of electric vehicles. The secondary batteries are expected to increase in demand in the future to overcome problems such as resource depletion and global environmental destruction caused by fossil fuels. Recently, as batteries have become larger in capacity, large-capacity battery cells of 100 A or more are being developed and distributed as unit battery cells.

Describing a manufacturing process of the secondary battery, the manufacturing process of the secondary battery mainly includes an electrode generation process, an assembly process, and a formation process. The electrode generation process is a process of generating a positive electrode and a negative electrode of the secondary battery, the assembly process is a process of stacking electrodes and a separator and rolling the electrodes and the separator to wrap the electrodes and the separator with an aluminum sheet, and the formation process is a process of making the secondary battery actually usable by charging and discharging the secondary battery to form a chemical material inside the secondary battery. Among these processes, the formation process is a process in which the most time is required. When the assembly of the battery cell is completed, the formation process goes through a pre-charging process of removing (de-gassing) gas generated from a cell while initially charging a battery cell to a SOC level of about 30% at a constant current, and a main charging process of charging the battery cell to the SOC of 100% and then discharging the battery cell again.

The current formation process adopts a method of performing formation by attaching a separate charging and discharging device to each battery cell, so in order to increase the productivity of the secondary battery, numerous formation devices should be used, and since cables should be connected separately to each battery cell, it has the problem of taking up a lot of space. In particular, a thick cable should be connected in order to form a large-capacity battery cell of 100 A or more, and thus, a space problem and a high-cost problem are serious.

In order to solve these problems, manners of charging and discharging a plurality of battery cells by a single charging and discharging device in a state of connecting the plurality of battery cells to each other in series are being studied. In this case, there is an advantage of reducing the cost and cable harness of the formation equipment and drastically reducing the size of the formation equipment by connecting the plurality of battery cells in series and performing the charging and discharging at once. However, there is a problem that charging is not balanced between the battery cells due to a capacity deviation between the battery cells. Recently, to solve this problem, a method has been proposed to perform battery cell balancing by controlling a charging time and a bypass time of each battery cell by attaching a charging switch connected in series to each battery cell and a bypass switch that short-circuits the charging switch and the battery cell.

Nevertheless, for pouch-type cells with electrodes arranged at both ends, there is still a limitation in that the cable structure for connecting a plurality of battery cells in series is complicated. For example, in the case of a serial battery charging and discharging device equipped with a bypass switch as described above, there is a disadvantage in that the structure is complicated and the cost is high because the bypass cable should be additionally connected to each battery cell to connect the bypass switch in addition to the connection cable.

### DISCLOSURE

### Technical Problem

The present disclosure has been made to solve the above problems, and an object of the present disclosure is to provide a serial connection structure of a battery cell applied to a serial battery charging and discharging device, which includes a plurality of pouch-type battery cells connected in series, a charging switch connected in series to each battery cell, and a bypass switch for short-circuiting the charging switch and both ends of the battery cell, in which the structure of a harness cable for connecting a plurality of battery cells in series by changing the power circuit configuration is simplified, thereby dramatically shortening a cable length and minimizing loss due to the cable and the cost for a cable connection, and a structure therefor.

### Technical Solution

In one general aspect, a serial connection structure of a battery cell applied to a serial battery charging and discharging device that performs charging or discharging by serially connecting a plurality of pouch-type battery cells with electrodes arranged at both ends thereof includes: one or more trays in which the plurality of pouch-type battery cells are received horizontally; a charging switch connected to each of the pouch-type battery cells in series; and a bypass switch connected to both ends of the serially connected pouch-type battery cell and the charging switch, in which the plurality of pouch-type battery cells are configured to include a plurality of alternating battery pairs including a first battery in which (+) electrodes are arranged in one direction, and a second battery cell in which (+) electrodes are arranged in an opposite direction to the first battery cell and connected in series to the first battery cell,

a first charging switch and a first bypass switch of the first battery cell are connected series to the (+) electrodes at the ends of the plurality of alternating battery pairs, a second charging switch and a second bypass switch of the second battery cell are connected in series to (−) electrodes, and the ends of the first and second bypass switches are connected to each other,

the serial connection structure includes a common bypass cable connected between a point where the first battery cell and the second battery cell are connected in series and a point where the first and second bypass switches are connected to each other, and

the alternating battery pairs adjacent to each other are connected to each other through a connection cable that connects between the point where the second charging switch and the second bypass switch of one alternating battery pair are connected to each other and the point where the first charging switch and the first bypass switch of another alternating battery pair are connected to each other.

### Advantageous Effects

As described above, in the case of the serial battery charging and discharging device according to the present disclosure, it is possible to dramatically shorten the cable length by simplifying the structure of the harness cable for connecting the plurality of pouch-type battery cells in series, thereby minimizing the loss caused by the cable and the cost for the cable connection. Accordingly, the serial battery charging and discharging device according to the present disclosure has the advantages of lowering the cost, minimizing the size, and performing the formation process very efficiently.

### BRIEF DESCRIPTION OF THE DRAWINGS

FIG. 1 is a conceptual diagram of a pouch-type battery formation device.

FIG. 2 is an example diagram of a connection of pouch-type battery cells in a conventional individual charging and discharging method.

FIG. 3 is a configuration diagram of a conventional serial battery charging and discharging device.

FIG. 4 is a circuit diagram of a conventional serial battery charging and discharging device.

FIG. 5 is an example diagram of the connection of the pouch-type battery cells in the conventional serial battery charging and discharging method.

FIG. 6 is a circuit diagram of a serial battery charging and discharging device according to the present disclosure.

FIG. 7 is a diagram for describing an alternating battery cell arrangement method in a tray for the connection of the pouch-type battery cells in the serial battery charging and discharging device according to the present disclosure.

FIG. 8 is a diagram for describing an alternating battery cell arrangement method in the tray for the connection of the pouch-type battery cells in the serial battery charging and discharging device according to the present disclosure.

### BEST MODE

A preferred embodiment of the present disclosure will be described in detail with reference to the accompanying drawings. The following detailed description is merely an example, and merely illustrates exemplary embodiments of the present disclosure.

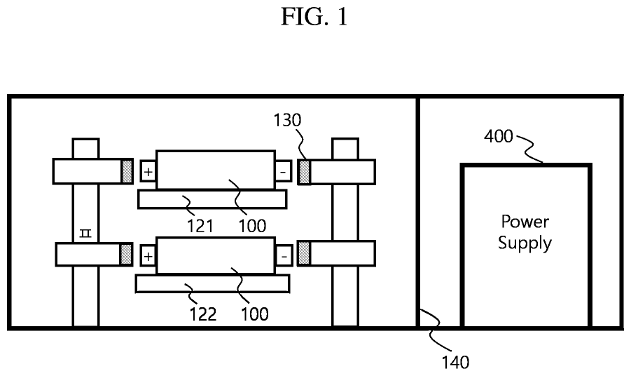

FIG. 1 is a conceptual diagram of a pouch-type battery formation device.

A battery that has been physically manufactured is actually operated so that it may be used by forming internal chemicals using a battery formation device. When the assembly of the battery cell is completed, the formation process goes through a pre-charging process of removing (de-gassing) gas generated from a cell while initially charging a battery cell to a SOC level of about 30% at a constant current, and a main charging process of charging the battery cell to the SOC of 100% and then discharging the battery cell again.

In relation to this, the battery formation device may be configured to include a power supply device 400 that rectifies and transforms AC electricity supplied from an external power source, and a battery charging and discharging device that performs the function of receiving electricity supplied from the power supply device 400 and charging a target battery.

The battery charging and discharging device for charging a pouch-type battery cell includes at least one tray 121 or 122 for accommodating a battery cell 100 to be charged within the device, and the trays 121 and 122 are formed in a plate shape having a thickness and have an accommodating space for accommodating at least one battery cell therein.

The battery charging and discharging device may include a unit charging and discharging unit that electrically connects to electrode leads of the plurality of battery cells 100 mounted on the trays 121 and 122 to perform an operation of charging and discharging a plurality of batteries, and the unit charging and discharging unit may be arranged to correspond to the plurality of battery cells one-to-one, and may include a plurality of charging and discharging grippers 130 for pressing the electrode leads of the corresponding battery cells.

A compartment 140 ensures that the power supply 400 and the battery cells are arranged in an isolated space from each other so that heat generated from the power supply device 400 does not affect the battery cells.

Meanwhile, in the battery charging and discharging device, in order to charge and discharge the battery cell, electricity should be supplied to the battery cell through a power supply, and for this purpose, a cable connection for electrical interconnection is required between battery cells or between the battery cell and the power supply device 400. This requires more complicated cable connection when the number of battery cells to be connected in series for charging and discharging increases.

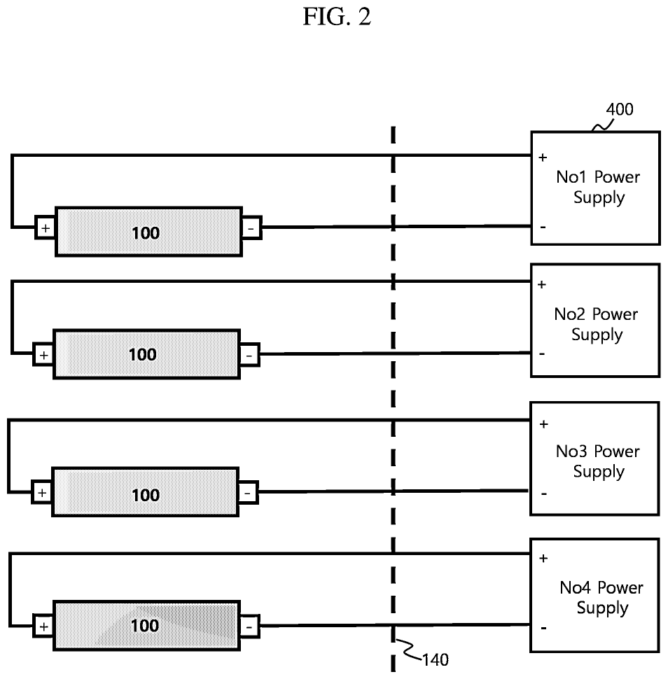

FIG. 2 is an example diagram of a wiring of pouch-type battery cells in a conventional individual charging and discharging method. FIG. 2 illustrates an example of a cable connection form in a case where the individual power supply device 400 is attached to each battery cell to perform charging and discharging.

Referring to FIG. 2, in the case of an individual connection method, electrodes corresponding to each battery cell are separately provided for each power supply device 400, and a structure is formed in which cables are individually connected from each electrode of the battery cell to the corresponding electrode of the individual power supply device 400. However, this has the problem that the cable length connecting the power supply device 400 and the (+) and (−) electrodes of the battery cell is long, which leads to problems of a lot of space for cable connection and the high cost and high loss.

In order to solve these problems, manners of charging and discharging a plurality of battery cells by a single charging and discharging device in a state of connecting the plurality of battery cells to each other in series are being studied. In this case, there is an advantage of reducing the cost and cable harness of the formation equipment and drastically reducing the size of the formation equipment by connecting the plurality of battery cells in series and performing the charging and discharging at once. However, there is a problem that charging is not balanced between the battery cells due to a capacity deviation between the battery cells.

Recently, to solve this problem, a method has been proposed to perform battery cell balancing by controlling a charging time and a bypass time of each battery cell by attaching a charging switch connected in series to each battery cell and a bypass switch that short-circuits the charging switch and the battery cell.

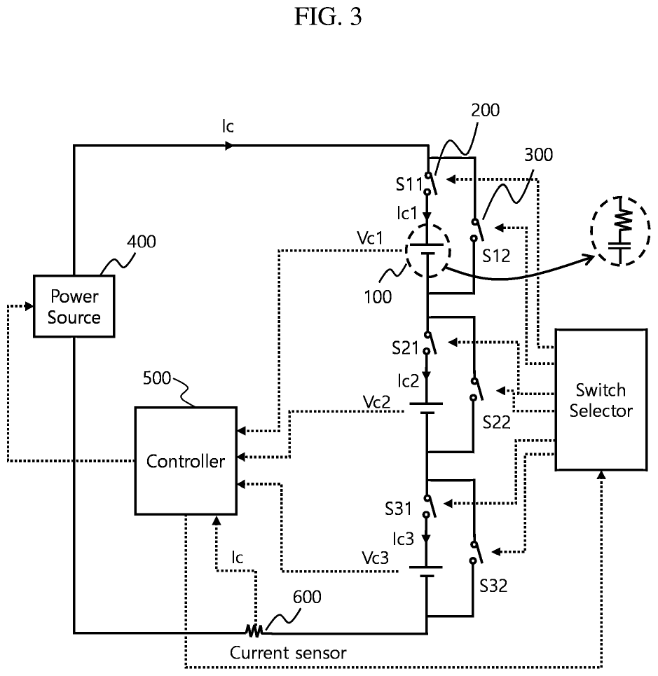

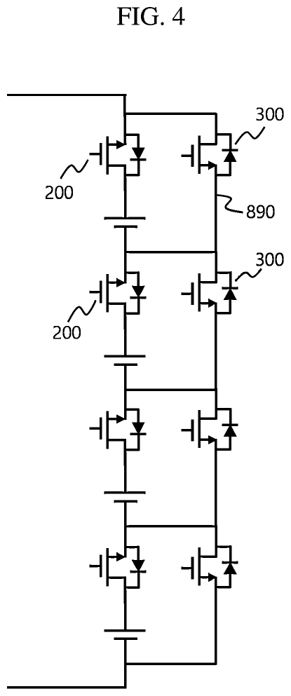

FIG. 3 and FIG. 4 are a configuration diagram and a circuit diagram of the conventional serial battery charging and discharging device. For example, referring to FIGS. 3 and 4, the conventional charging and discharging device may include a battery in which the plurality of battery cells 100 are connected in series, a charging switch 200 connected in series to each battery cell 100, a bypass switch 300 that short-circuits both ends of each battery cell 100 and the charging switch 200, a voltage sensor (not illustrates) that senses the voltage of each battery cell 100, a current sensor 600 that measures the charging and discharging current, a charging and discharging power supply device 400 that provides the charging and discharging current, and a controller 500.

The conventional serial battery charging and discharging device is configured to include the charging switch 200 connected in series to the battery cell and the bypass switch 300 that short-circuits both ends of the battery cell 100 and the charging switch 200 and operates as a toggle with the charging switch 200. When the charging switch for a specific battery cell is turned on, the corresponding battery cell is charged or discharged, and when the bypass switch is turned on, the corresponding battery cell is not charged or discharged and rests. This operation controls the plurality of battery cells to be charged and discharged at the same level.

In the case of the conventional serial battery charging and discharging device, there is an advantage in that battery cell balancing may be performed by adjusting the charging switch charging time and the bypass switch bypass time of each battery cell during the battery charging and discharging process.

In addition, since the plurality of battery cells are connected in series for charging and discharging, the cable length may be drastically reduced, which has the advantage of reducing cost, loss, and space. However, in the case of the conventional serial battery charging and discharging device configuration, there is still a limitation that the cable length should be long in order to connect the plurality of pouch-type battery cells with the electrodes arranged at both ends in series.

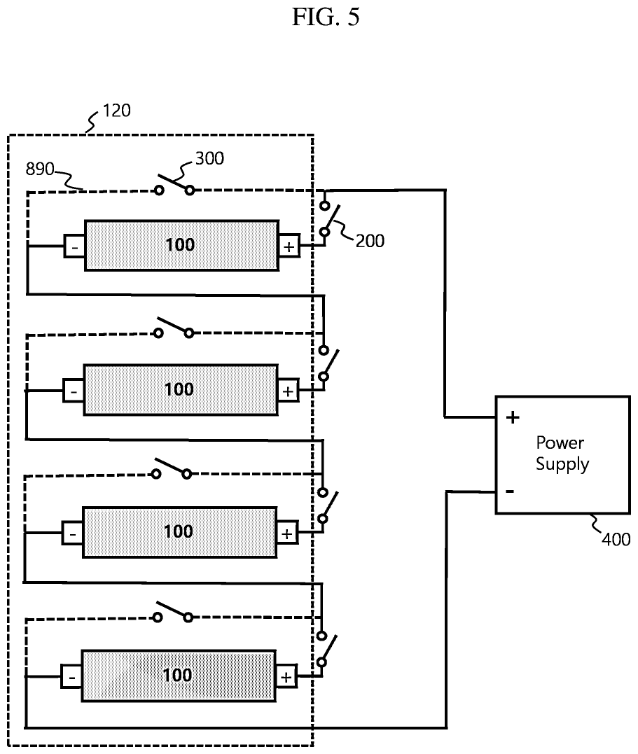

FIG. 5 is an example diagram of the connection of the pouch-type battery cells in the conventional serial charging and discharging method. For example, referring to FIG. 5, when connecting the plurality of pouch-type battery cells in series, it may be confirmed that the cable length (solid line) for the serial connection between adjacent battery cells is long. Furthermore, in the case of the conventional serial battery charging and discharging device configuration, since a bypass cable 890 should be additionally connected to each battery cell to connect the bypass switch, there is a disadvantage in that the structure is complicated and additional costs are incurred.

In order to overcome the limitations of the above-described serial battery charging and discharging device, the present disclosure proposes a new type of serial connection structure of a battery cell that may be implemented by simplifying the structure of the harness cable for connecting the plurality of pouch-type battery cells in series compared to the conventional structure. More specifically, the cable length is reduced compared to the conventional one by alternately arranging the electrode directions of the pouch-type battery cells connected in series to each other and by changing the arrangement of the charging switch 200 and the bypass switch 300, thereby reducing a lot of space for the cable connection and reducing the loss due to the cable.

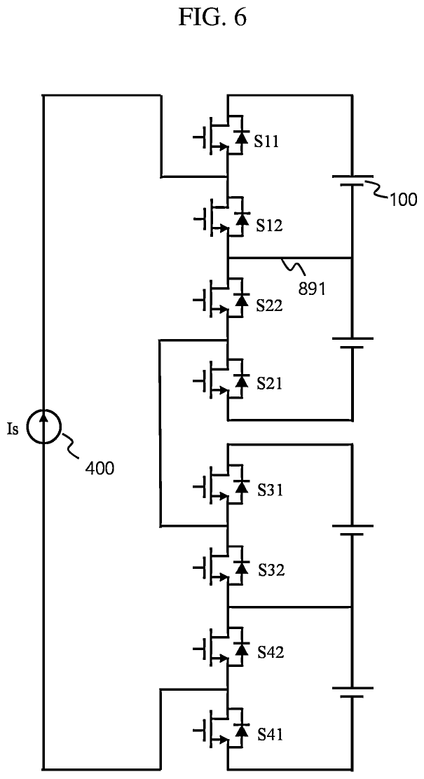

Hereinafter, with reference to FIGS. 6 to 8, a description will be given of the serial connection structure of the plurality of pouch-type battery cells applied to the serial battery charging and discharging device according to the present disclosure.

Similar to the conventional serial battery charging and discharging device, the serial battery charging and discharging device according to the present disclosure is configured to include the charging switch 200 that is connected in series to each battery cell 100 and the bypass switch 300 that short-circuits both ends of each battery cell 100 and the charging switch 200, and operates as the charging switch 200 and a toggle, as a basic configuration.

Here, each of the charging switch and the bypass switch may be a switch in which one active switch and one diode are connected in parallel in the opposite direction to each other.

In another embodiment, one of the charging switch and the bypass switch may be a structure in which two or more switches in which one active switch and one diode are connected in parallel in the opposite direction to each other are connected in series.

As described above, the serial battery charging and discharging device according to the present disclosure has a difference from the conventional one in the arrangement method of the battery cell 100, the charging switch 200, and the bypass switch 300 in order to simplify the structure of the cable for connecting the plurality of pouch-type battery cells in series and implement the structure more easily than the conventional one.

FIG. 6 is a circuit diagram of the serial battery charging and discharging device according to the present disclosure.

Referring to FIG. 6, the serial battery charging and discharging device according to the present disclosure changes the positions of the charging switch and the corresponding battery cells so that two battery cells are directly connected, compared to the conventional serial battery charging and discharging device of FIG. 4. That is, the positions of the charging switches are arranged symmetrically at each end of two adjacent battery cells connected in series so that two adjacent battery cells are directly connected. For example, when the position of the charging switch 200 is connected to a (+) terminal of a specific battery cell, it is connected to a (−) terminal of the next battery cell, and then to a (+) terminal of the next battery cell again, so it may be confirmed that the positions of the charging switches of the two adjacent battery cells are configured to be symmetrical to each other. By doing so, the power circuit configuration is simplified and the voltage and current sensing circuit of the cell is structurally easy.

In the case of the serial battery connection method according to the present disclosure, by alternately changing the electrode directions of the pouch-type battery cells connected in series to each other along with the arrangement of the charging switch 200, the cable length for connecting the plurality of pouch-type battery cells in series may be configured to be the shortest.

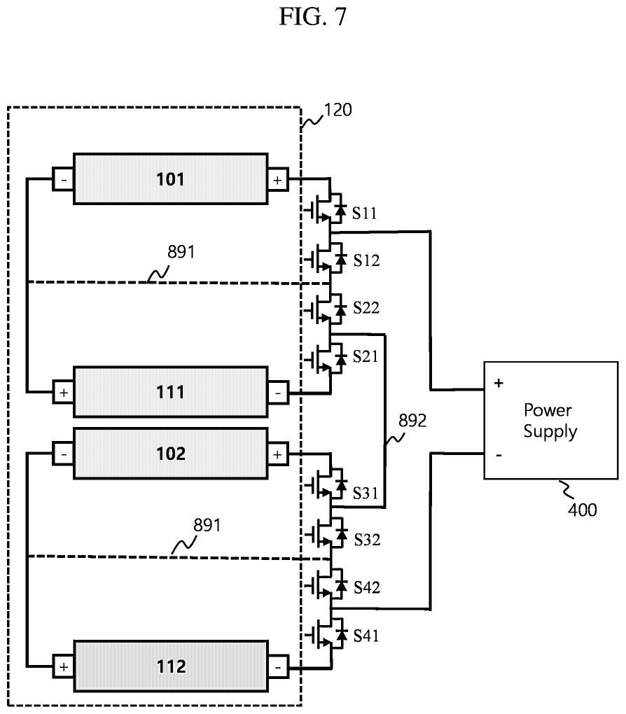

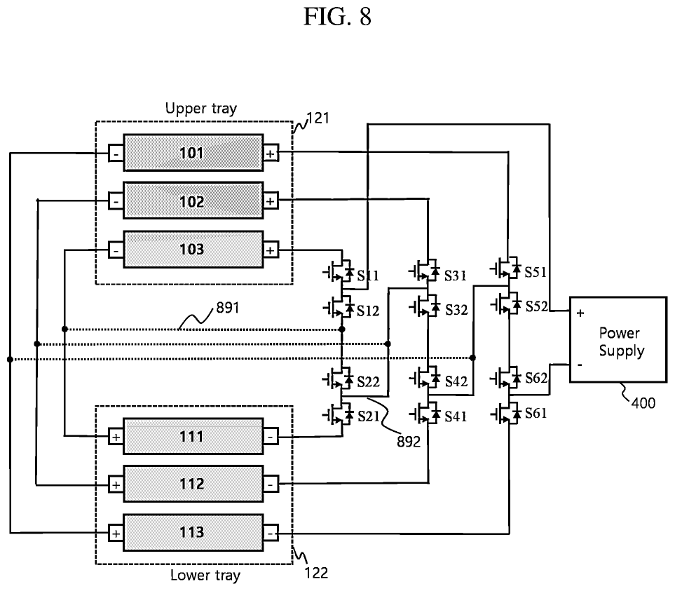

For example, FIG. 7 is a diagram for describing an alternating battery cell arrangement method in a tray for the connection of the pouch-type battery cells in the serial battery charging and discharging device according to t the present disclosure and FIG. 8 is a diagram for describing an alternating battery cell arrangement method in the tray for the connection of the pouch-type battery cells in the serial battery charging and discharging device according to the present disclosure.

Referring to FIG. 7, in the case of the serial battery charging and discharging device according to the present disclosure, the electrode directions of the pouch-type battery cells connected in series to each other may be alternately arranged by alternating the electrode directions of each battery cell accommodated in the same tray.

In another embodiment, referring to FIG. 8, in the case of the serial battery charging and discharging device according to the present disclosure, when the even number of trays 121 and 122 is provided, the arrangement directions of adjacent trays may be arranged alternately, so the electrode directions of battery cells accommodated in each tray may be arranged alternately, thereby allowing the electrode directions of the battery cells connected in series to be arranged alternately. Meanwhile, the above-described method of alternating battery cell arrangement may also be applied when the odd number of trays is provided. In the case of the structure in which the pouch-type battery cells connected in series are arranged alternately as described above, there is an advantage in that the cable length for connecting the battery cells in series is shortened compared to the conventional method because different electrodes are arranged adjacently. That is, in the conventional method in which the battery cells connected in series are arranged in one direction, the cable length becomes long and the cable becomes complicated because the connection cable should be connected to the left and right of a jig in order to connect the plurality of pouch-type battery cells in series. On the other hand, in the case of the present disclosure, the cable length may be configured to be shorter.

In addition, in the case of the serial battery connection method according to the present disclosure, there is no need to additionally connect the bypass cable to each battery cell in order to connect the bypass switch, and the conventional bypass function may be performed simply by connecting one bypass cable between pouch-type battery cells connected in series. This has the effect of reducing the number of bypass cables by half compared to the conventional method.

In this way, in the case of the serial battery connection method according to the present disclosure, the loss caused by the cable may be minimized by minimizing the cable length for connecting the battery cells in series. Meanwhile, in the case of the bypass cable, unlike the general connection cable, since no current flows normally and only the bypass current flows by bypassing the battery cell when charging or discharging, there is no additional loss.

Hereinafter, the serial battery connection method according to the present disclosure will be described in more detail.

In the present disclosure, the plurality of pouch-type battery cells connected in series may be configured to include a plurality of alternating battery pairs including first battery cells 101, 102, and 103 in which the (+) electrodes are arranged in one direction, and second battery cells 111, 112, and 113 in which (+) electrodes are arranged in the opposite direction to the first battery cell 101 and are connected in series to the first battery cells 101, 102, and 103.

The first and second battery cells included in the plurality of alternating battery pairs may be arranged on the same tray.

Alternatively, when it is difficult to arrange alternately within the tray, the directions of the upper tray 121 and the lower tray 122 may be reversed to implement the arrangement so that the entire tray is arranged alternately, and each tray may be provided separately.

In this case, the first charging switch and the first bypass switch of the first battery cell are connected in series to the (+) electrode at the end of the plurality of alternating battery pairs, the second charging switch and the second bypass switch of the second battery cell are connected in series to the (−) electrode, and the ends of the first and second bypass switches are connected to each other.

It is configured to include a common bypass cable 891 connected between the point where the first battery cell and the second battery cell are connected in series and the point where the first and second bypass switches are connected to each other.

The adjacent alternating battery pairs are connected to each other through a connection cable 892 that connects between the point where the second charging switch and the second bypass switch of one alternating battery pair are connected to each other and the point where the first charging switch and the first bypass switch of another alternating battery pair are connected to each other.

In addition, the (+) terminal of the power supply is connected to the point where the first charging switch and the first bypass switch of the alternating battery pair located at the top of the alternating battery pair are connected, and the (−) terminal of the power supply is connected to the point where the second charging switch and the second bypass switch of the alternating battery pair located at the bottom of the alternating battery pair are connected.

Meanwhile, in the present disclosure, the case where the first and second battery cells are arranged in the same tray and the case where the first and second battery cells are arranged in adjacent trays are described as different embodiments, but it is not necessarily limited thereto. For example, the serial connection structure of the battery cells according to the present disclosure may also be applied to the case where the first and second battery cells of each of some of the alternating battery pairs among the plurality of alternating battery pairs are arranged in the same tray, and the first and second battery cells of each of the remaining alternating battery pairs among the plurality of alternating battery pairs are arranged in adjacent trays.

Although exemplary embodiments of the present disclosure have been disclosed hereinabove with reference to the present specification and the drawings and specific terms have been used, they are merely used in a general sense in order to easily describe technical contents of the present disclosure and assist in the understanding of the present, and are not intended to limit the scope of the present disclosure. It will be apparent to those of ordinary skill in the art that other modifications based on the technical idea of the present disclosure are possible, in addition to exemplary embodiments disclosed herein.

[Description of Reference Signs]

| | |
|---|---|
| 100: Pouch-type cell | |
| 101, 102, 103: First battery cell | 111, 112, 113: Second battery cell |
| 120: Tray | |
| 121: Upper tray | 122: Lower tray |
| 130: Gripper | 140: Compartment between jig unit |
| | and charging unit |
| 200, S11, S21, S31, S41, S51: Charging switch | |
| 300, S12, S22, S32, S42, S52: Bypass switch | |
| 400: Charging and discharging power supply device | |
| 500: Controller | 600: Current sensor |
| 890: Bypass cable | |
| 891: Common bypass cable | 892: Connection cable |

1. A serial connection structure of a battery cell applied to a serial battery charging and discharging device that performs charging or discharging by serially connecting a plurality of pouch-type battery cells with electrodes arranged at both ends thereof, the serial connection structure comprising:
one or more trays in which the plurality of pouch-type battery cells are received horizontally;
a charging switch connected to each of the pouch-type battery cells in series;
a bypass switch connected to both ends of the serially connected pouch-type battery cell and the charging switch; and
a common bypass cable connected between a point where a first battery cell and a second battery cell are connected in series and a point where a first bypass switch and a second bypass switch are connected to each other,
wherein the plurality of pouch-type battery cells are configured to include a plurality of alternating battery pairs including a first battery cell in which (+) electrodes are arranged in one direction, and a second battery cell in which (+) electrodes are arranged in an opposite direction to the first battery cell and connected in series to the first battery cell,
a first charging switch and a first bypass switch of the first battery cell are connected in series to the (+) electrodes at the ends of the plurality of alternating battery pairs, a second charging switch and a second bypass switch of the second battery cell are connected in series to (−) electrodes, and the ends of the first and second bypass switches are connected to each other, and
the alternating battery pairs adjacent to each other are connected to each other through a connection cable that connects between the point where the second charging switch and the second bypass switch of one alternating battery pair are connected to each other and the point where the first charging switch and the first bypass switch of another alternating battery pair are connected to each other.

2. The serial connection structure of claim 1, wherein the first and second battery cells are arranged alternately within the same tray.

3. The serial connection structure of claim 1, wherein the tray is provided in an even number, and
the first battery cell and the second battery cell are each arranged in adjacent trays.
